(19) United States
(12) Patent Application Publication
(10) Pub. No.: US 2014/0117374 A1
(43) Pub. Date: May 1, 2014

(54) SEMICONDUCTOR DEVICE

(71) Applicant: SAMSUNG ELECTRO-MECHANICS CO., LTD., Suwon (KR)

(72) Inventors: Jae Hoon Park, Suwon (KR); Chang Su Jang, Suwon (KR); In Hyuk Song, Suwon (KR); Kee Ju Um, Suwon (KR); Dong Soo Seo, Suwon (KR)

(73) Assignee: SAMSUNG ELECTRO-MECHANICS CO., LTD., Suwon (KR)

(21) Appl. No.: 13/758,946

(22) Filed: Feb. 4, 2013

(30) Foreign Application Priority Data
Oct. 29, 2012 (KR) 10-2012-0120393

(51) Int. Cl. H01L 29/20; H01L 29/00

(52) U.S. Cl. CPC H01L 29/2003; H01L 29/00
USPC 257/76; 257/183

(57) ABSTRACT

Disclosed herein is a semiconductor device including: a base substrate; a first nitride semiconductor layer formed on the base substrate; a second nitride semiconductor layer formed on the first nitride semiconductor layer; a cathode electrode formed on one side of the second nitride semiconductor layer; an anode electrode having one end and the other end, one end being recessed at the other side of the second nitride semiconductor layer up to a predetermined depth, and the other end being spaced apart from the cathode electrode and formed to be extended up to an upper portion of the cathode electrode; and an insulating film formed on the second nitride semiconductor layer between the anode electrode and the cathode electrode so as to cover the cathode electrode.

### CROSS REFERENCE TO RELATED APPLICATION

This application claims the benefit of Korean Patent Application No. 10-2012-0120393, filed on Oct. 29, 2012, entitled “Semiconductor Device”, which is hereby incorporated by reference in its entirety into this application.

### BACKGROUND OF THE INVENTION

1. Technical Field

The present invention relates to a semiconductor device.

2. Description of the Related Art

In general, a semiconductor device is classified into an active device and a passive device, and the active device is used for configuring a circuit such as a voltage regulator, a current regulator, an oscillator, a logic gate, or the like at the time of amplification.

Among the active devices, a diode is widely used as a detection device, a current device, and a switching device. An example of representative diodes includes a voltage regulator diode, a variable capacitance diode, a photo diode, a light emitting diode (LED), a Zener diode, a Gunn diode, a Schottky diode, and the like.

The Schottky diode among the above-described diodes, which is a diode using a Schottky junction having a junction of a metal and a semiconductor, has an advantage that a switching operation is possible at a high speed, and the diode can be driven by low forward voltage.

In general, the Schottky diode may be configured of an anode electrode forming a Schottky contact, a cathode electrode forming an ohmic contact, and a 2-Dimensional Electron Gas (2DEG) channel formed by heterojunction of AlGaN/GaN.

Here, current transport between the anode electrode and the cathode electrode is performed by the 2DEG channel.

Meanwhile, a structure of the Schottky diode of the prior art is disclosed in U.S. Pat. No. 6,768,146.

### SUMMARY OF THE INVENTION

The present invention has been made in an effort to provide a semiconductor device capable of increasing a current transport amount by additionally forming a current transport path.

According to a preferred embodiment of the present invention, there is provided a semiconductor device including: a base substrate; a first nitride semiconductor layer formed on the base substrate; a second nitride semiconductor layer formed on the first nitride semiconductor layer; a cathode electrode formed on one side of the second nitride semiconductor layer; an anode electrode having one end and the other end, one end being recessed at the other side of the second nitride semiconductor layer up to a predetermined depth, and the other end being spaced apart from the cathode electrode and formed to be extended up to an upper portion of the cathode electrode; and an insulating film formed on the second nitride semiconductor layer between the anode electrode and the cathode electrode so as to cover the cathode electrode.

The cathode electrode may be recessed into the second nitride semiconductor layer up to a predetermined depth.

The insulating film may include a first part contacting the second nitride semiconductor layer; and a second part contacting the cathode electrode, the second part having a thickness thicker than that of the first part.

The first nitride semiconductor layer may be made of gallium nitride (GaN).

The second nitride semiconductor layer may be made of aluminum gallium nitride (AlGaN).

The insulating film may be an oxide film.

The oxide film may be made of silicon dioxide (SᵢO₂).

The anode electrode may be made of nickel (Ni).

The cathode electrodes may be laminated in an order of titanium(Ti)/nickel(Ni)/aluminum(Al)/gold(Au).

The anode electrode may form a Schottky contact.

The cathode electrode may form an ohmic contact.

According to another preferred embodiment of the present invention, there is provided a semiconductor device including: a base substrate; a first nitride semiconductor layer formed on the base substrate; a second nitride semiconductor layer formed on the first nitride semiconductor layer; a cathode electrode formed on one side of the second nitride semiconductor layer; an anode electrode having one end and the other end, one end being recessed into the other side of the second nitride semiconductor layer up to a predetermined depth, and the other end being spaced apart from the cathode electrode and formed to be extended up to an upper portion of the cathode electrode; and an insulating film formed on the second nitride semiconductor layer between the anode electrode and the cathode electrode so as to cover the cathode electrode, wherein the insulating film includes a first part contacting the second nitride semiconductor; and a second part contacting the cathode electrode, the second part having a thickness thicker than that of the first part.

The cathode electrode may be recessed into the second nitride semiconductor layer up to a predetermined depth.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a structure of a semiconductor device according to a preferred embodiment of the present invention; and

FIG. 2 is a cross-sectional view showing a structure in which a thickness of an insulating film contacting a second nitride semiconductor layer and a thickness of an insulating film contacting a cathode electrode are different in the semiconductor device of FIG. 1.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

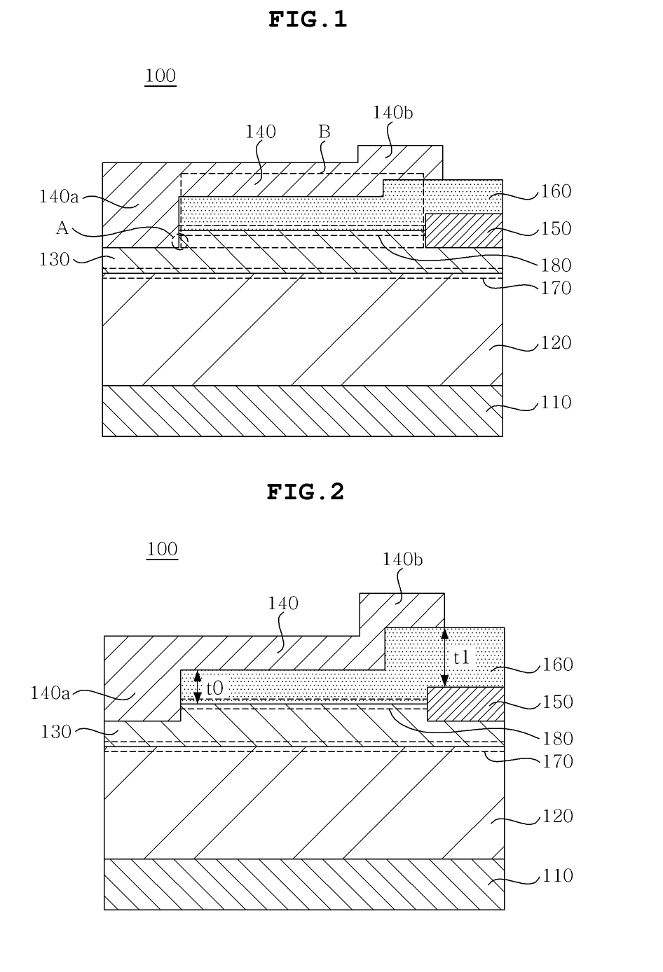

FIG. 1 is a cross-sectional view showing a structure of a semiconductor device according to a preferred embodiment of the present invention; and FIG. 2 is a cross-sectional view showing a structure in which a thickness of an insulating film contacting a second nitride semiconductor layer and a thickness of an insulating film contacting a cathode electrode are different in the semiconductor device of FIG. 1.

Referring to FIG. 1, the semiconductor device 100 according to the preferred embodiment of the present invention includes a base substrate 110; a first nitride semiconductor layer 120 formed on the base substrate 110; a second nitride semiconductor layer 130 formed on the first nitride semiconductor layer 120; an anode electrode 140 and a cathode electrode 150 formed on the second nitride semiconductor layer 130 so as to be spaced apart from each other; and an insulating film 160 formed on the second nitride semiconductor layer 130 so as to cover the cathode electrode 150. The base substrate 110 of the preferred embodiment of the present invention, which is a plate for forming the semiconductor device, may be a semiconductor substrate.

Here, the semiconductor substrate may be at least any one of a silicon substrate, a silicon carbide substrate, and a sapphire substrate; however, the present invention is not particularly limited thereto.

In the preferred embodiment of the present invention, the first nitride semiconductor layer 120 and the second nitride semiconductor layer 130 may include a Group III-nitride based material. More specifically, the Group In-nitride based material may be any one from gallium nitride (GaN), aluminum gallium nitride (AlGaN), indium gallium nitride (InGaN), and indium aluminum gallium nitride (InAlGaN); however, the present invention is not limited thereto.

In addition, the second nitride semiconductor layer 130 of the preferred embodiment of the present invention may be made of a material having an energy band gap wider than that of the first nitride semiconductor layer 120; however, the present invention is not limited thereto.

In addition, the second nitride semiconductor layer 130 may be made of a material having a lattice constant different from that of the first nitride semiconductor layer 120; however, the present invention is not limited thereto.

As one example, the first nitride semiconductor layer 120 may be made of gallium nitride (GaN), and the second nitride semiconductor layer 130 may be made of aluminum gallium nitride (AlGaN).

A 2-dimensional electron gas (2DEG) channel 170 may be formed on an interface between the first nitride semiconductor layer 120 and the second nitride semiconductor layer 130 according to the above-described example, as shown in FIG. 1. At the time of operating the semiconductor device 100, a current flow may be achieved through the formed 2DEG channel 170.

Meanwhile, a separate buffer layer (not-shown) may be further formed between the base substrate 110 and the first nitride semiconductor layer 120 in order to solve problems according to a lattice mismatch between the base substrate 110 and the first nitride semiconductor layer 120.

Here, the buffer layer (not-shown) may be made of aluminum nitride (AlN); however, the present invention is not particularly limited thereto.

In the preferred embodiment of the present invention, the cathode electrode 150 may be formed on the second nitride semiconductor layer 130. Here, the cathode electrode 150 may be formed on one side of the second nitride semiconductor layer 130; however, the present invention is not particularly limited thereto, and the cathode electrode 150 may be recessed into the second nitride semiconductor layer 130 up to a predetermined depth as shown in FIG. 1.

Here, the cathode electrodes 150 may be laminated in an order of titanium(Ti)/nickel(Ni)/aluminum(Al)/gold(Au); however, the present invention is not limited thereto.

In addition, the cathode electrode 150 may form an ohmic contact with the second nitride semiconductor layer 130; however, the present invention is not particularly limited thereto.

In the preferred embodiment of the present invention, the anode electrode 140 may be formed on the second nitride semiconductor layer 130 so as to be spaced apart from the above-described cathode electrode 150.

More specifically, as shown in FIG. 1, the anode electrode 140 may have one end 140a and to the other end 140b, one end 140a being recessed into the other side of the second nitride semiconductor layer 130 up to a predetermined depth, and the other end 140b formed to be extended up to an upper portion of the cathode electrode 150.

Here, the anode electrode 140 may be spaced apart from the cathode electrode 150.

That is, the anode electrode 140 of the preferred embodiment of the present invention is extended from the other side of the second nitride semiconductor layer 130 to the cathode electrode 150 while being spaced apart from the cathode electrode 150.

As described above, as one end 140a of the anode electrode 140 is recessed into the second nitride semiconductor layer 130 up to a predetermined depth, at the time of forward bias, electrons may be easily injected from the anode electrode 140 to a junction portion of the second nitride semiconductor layer 130 and the insulating film 160 through part A of FIG. 1 due to a Schottky bather lowering effect.

In addition, the anode electrode 140 may be made of nickel (Ni); however, the present invention is not particularly limited thereto. In addition, the anode electrode 140 may form a Schottky contact with the second nitride semiconductor layer 130; the present invention is not particularly limited thereto.

Further, the insulating film 160 of the preferred embodiment of the present invention may be formed on the second nitride semiconductor layer 130 between the anode electrode 140 and the cathode electrode 150 so as to cover the cathode electrode 150.

Here, the insulating film 160 may contact the anode electrode 140 extended to the cathode electrode 150 on a surface opposite to a surface that the second nitride semiconductor layer 130 and the cathode electrode 150 contact to each other.

That is, the anode electrode 140 extended to an upper portion of the cathode electrode 150 may be electrically insulated with the cathode electrode 150 by the insulating film 160.

In the preferred embodiment of the present invention, the insulating film 160 may be an oxide film; however, the present invention is not particularly limited thereto. Here, the oxide film may be made of silicon dioxide (SᵢO₂); however, the present invention is not particularly limited thereto.

As described above, as the second nitride semiconductor layer 130 has the anode electrode 140, the insulating film 160, and the cathode electrode 150 formed thereon, a metal-oxide-semiconductor (MOS) structure is formed between one end 140a of the anode electrode 140 and the cathode electrode 150 as shown in part B of FIG. 1.

Hereinafter, a general operation principle of the MOS structure will be briefly described.

When bias is applied to a metal in the MOS structure, the applied bias appears on the oxide layer and the semiconductor layer as an electric field. In this case, most of the bias appears as an electric field in the oxide layer, and some of the bias only functions on the semiconductor layer to cause a band bending on the surface of the semiconductor layer.

Here, when bias is enough, the band bending is sufficiently generated to reduce a conduction band under a Fermi level, whereby the surface of the semiconductor layer is inversed to form a channel, that is, a portion in which electrons are collected.

That is, the anode electrode 140 is formed so as to be extended from the other side of the second nitride semiconductor layer 130 to the upper portion of the cathode electrode 150 formed on one side of the second nitride semiconductor layer 130, and the insulating film 160 is formed between the anode electrode 140 and the second nitride semiconductor layer 130, such that a serial structure of “anode electrode-insulating film-second nitride semiconductor layer” may be formed as shown in part B of FIG. 1.

The structure corresponds to the MOS structure, that is, a structure of “metal—oxide film—to semiconductor layer”. Therefore, in accordance with the operation principle of the above-described MOS structure, a current transport channel 180 may also be formed on an interface between the second nitride semiconductor layer 130 and the insulating film 160 as shown in FIG. 1 in the preferred embodiment of the present invention.

As the current transport channel 180 is formed on the interface between the second nitride semiconductor layer 130 and the insulating film 160 as described above, the electrons injected from the anode electrode 140 recessed into the second nitride semiconductor layer 130 to the junction portion of the second nitride semiconductor layer 130 and the insulating film 160 through part A of FIG. 1 flow to the cathode electrode 150 through the current transport channel 180.

That is, the semiconductor device 100 according to the preferred embodiment of the present invention includes the current transport channel 180 further formed between the second nitride semiconductor layer 130 and the insulating film 160, in addition to the 2DEG channel 170 formed on the interface between the first nitride semiconductor layer 120 and the second nitride semiconductor layer 130.

Therefore, since current may be transported by the further formed current transport channel 180 as well as the 2DEG channel 170, larger amount of current may be transported at one time as compared to the Schottky diode of the prior ark

Meanwhile, when reverse bias is applied between the anode electrode 140 and the cathode electrode 150, a structure in which the insulating film 160 formed between the cathode electrode 150 and the other end 140b of the anode electrode 140 formed in the upper portion of the cathode electrode 150 has a thick thickness in order to increase breakdown voltage and decrease leakage current is shown in FIG. 3.

That is, as shown in FIG. 3, a thickness t0 of the insulating film 160 formed between the anode electrode 140 and the second nitride semiconductor layer 130 and a thickness t1 of the insulating film 160 formed between the anode electrode 140 and the cathode layer 150 are thick to thereby increase reverse voltage capability between the anode electrode 140 and the cathode electrode 150 at the time of reverse bias.

The oxide film and the anode electrode are extended on the nitride semiconductor layer and the channel capable of transporting the current between the nitride semiconductor layer and the oxide film is additionally formed, thereby making it possible to transport the large amount of current at one time.

In addition, the anode electrode is recessed into the nitride semiconductor layer up to a predetermined depth, whereby the electron may be easily injected from the anode electrode to the semiconductor layer.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A semiconductor device comprising:
a base substrate;
a first nitride semiconductor layer formed on the base substrate;
a second nitride semiconductor layer formed on the first nitride semiconductor layer;
a cathode electrode formed on one side of the second nitride semiconductor layer;
an anode electrode having one end and the other end, one end being recessed at the other side of the second nitride semiconductor layer up to a predetermined depth, and the other end being spaced to apart from the cathode electrode and formed to be extended up to an upper portion of the cathode electrode; and
an insulating film formed on the second nitride semiconductor layer between the anode electrode and the cathode electrode so as to cover the cathode electrode.

2. The semiconductor device as set forth in claim 1, wherein the cathode electrode is recessed into the second nitride semiconductor layer up to a predetermined depth.

3. The semiconductor device as set forth in claim 1, wherein the insulating film includes:
a first part contacting the second nitride semiconductor layer; and
a second part contacting the cathode electrode,
the second part having a thickness thicker than that of the first part.

4. The semiconductor device as set forth in claim 1, wherein the first nitride semiconductor layer is made of gallium nitride (GaN).

5. The semiconductor device as set forth in claim 1, wherein the second nitride semiconductor layer is made of aluminum gallium nitride (AlGaN).

6. The semiconductor device as set forth in claim 1, wherein the insulating film is an oxide film.

7. The semiconductor device as set forth in claim 6, wherein the oxide film is made of to silicon dioxide (SᵢO₂).

8. The semiconductor device as set forth in claim 1, wherein the anode electrode is made of nickel (Ni).

9. The semiconductor device as set forth in claim 1, wherein the cathode electrodes are laminated in an order of titanium(Ti)/nickel(Ni)/aluminum(Al)/gold(Au).

10. The semiconductor device as set forth in claim 1, wherein the anode electrode forms a Schottky contact.

11. The semiconductor device as set forth in claim 1, wherein the cathode electrode forms an ohmic contact.

12. A semiconductor device comprising:
a base substrate;
a first nitride semiconductor layer formed on the base substrate;
a second nitride semiconductor layer formed on the first nitride semiconductor layer;
a cathode electrode formed on one side of the second nitride semiconductor layer;
an anode electrode having one end and the other end, one end being recessed into the other side of the second nitride semiconductor layer up to a predetermined depth, and the other end being spaced apart from the cathode electrode and formed to be extended up to an upper portion of the cathode electrode; and
an insulating film formed on the second nitride semiconductor layer between the anode electrode and the cathode electrode so as to cover the cathode electrode,
wherein the insulating film includes:
a first part contacting the second nitride semiconductor; and
a second part contacting the cathode electrode,
the second part having a thickness thicker than that of the first part.

13. The semiconductor device as set forth in claim 12, wherein the cathode electrode is recessed into the second nitride semiconductor layer up to a predetermined depth.
